(19) United States
(12) Patent Application Publication
(10) Pub. No.: US 2016/0300857 A1
(43) Pub. Date: Oct. 13, 2016

(54) JUNCTIONLESS FINFET DEVICE AND METHOD FOR MANUFACTURE

(71) Applicant: STMicroelectronics, Inc., Coppell, TX (US)

(72) Inventors: Qing Liu, Watervliet, NY (US); John Hongguang Zhang, Fishkill, NY (US); Walter Kleemeier, Saratoga Springs, NY (US)

(73) Assignee: STMicroelectronics, Inc., Coppell, TX (US)

(21) Appl. No.: 14/680,392

(22) Filed: Apr. 7, 2015

(51) Int. Cl. H01L 27/12; H01L 29/417; H01L 27/092; H01L 21/324; H01L 21/306; H01L 29/08; H01L 21/84

(52) U.S. Cl. CPC H01L 27/1211; H01L 29/0847; H01L 29/41783; H01L 21/845; H01L 21/324; H01L 21/30604; H01L 27/0924

(57) ABSTRACT

A junctionless field effect transistor on an insulating layer of a substrate includes a fin made of semiconductor material doped with a dopant of a first conductivity type. A channel made of an epitaxial semiconductor material region doped with a dopant of a second conductivity type is in contact with a top surface of the fin. An insulated metal gate straddles the channel. A source connection is made to the epitaxial semiconductor material region on one side of said insulated metal gate, and a drain connection is made to the epitaxial semiconductor material region on an opposite side of said insulated metal gate. The epitaxial channel may further be grown from and be in contact with opposed side surfaces of the fin.

### TECHNICAL FIELD

The present invention relates to integrated circuits and, in particular, to a junctionless field effect transistor (FET) device fabricated using a fin of semiconductor material.

### BACKGROUND

The prior art teaches the formation of integrated circuits which utilize one or more junctionless field effect transistor (FET) devices. The junctionless FET device differs from a conventional junction transistor device in that the junctionless FET does not include current conduction structures defined by junctions between semiconductor regions. For example, a junctionless FET does not include current carrying junction between semiconductor regions doped to opposite conductivity type, this characteristic being in contrast to the p-n junctions which are present, for example, between the source/drain and channel regions of a MOSFET or between the emitter/collector and base regions of a bipolar transistor. The current carrying structure (i.e., the channel) of a junctionless FET device is instead formed of a single conductivity-type semiconductor region whose mobile carrier density is modulated by a bias voltage applied to an insulated gate electrode. In the off state, the channel is turned off by depletion of carriers due to the difference in work function between the semiconductor region and the gate material. In the on state, the channel functions as a variable resistive circuit path.

By eliminating the use of semiconductor junctions, the junctionless FET presents an attractive device in small scale low power, low voltage applications. However, junctionless FET devices may exhibit relatively high leakage due to the difficulty in completely turning off the device and the channel may exhibit a relatively high resistance in the on state. There is accordingly a need in the art to address the foregoing and other issues to provide a junctionless transistor of improved configuration, wherein manufacture of the device is compatible with CMOS process technologies.

### SUMMARY

In an embodiment, an integrated circuit transistor device comprises: an insulating layer of a substrate, a fin on said insulating layer, said fin comprising: a first portion of semiconductor material doped with a dopant of a first conductivity type; and a second portion of semiconductor material doped with a dopant of a second conductivity type, said second portion comprising epitaxial material grown from and in contact with a top surface of the first portion of semiconductor material; an insulated metal gate straddling said fin; a source connection to the second portion of semiconductor material on one side of said insulated metal gate; and a drain connection to the second portion of semiconductor material on an opposite side of said insulated metal gate.

In an embodiment, a method comprises: patterning semiconductor material doped with a dopant of a first conductivity type to form a fin on an insulating layer of a substrate; epitaxially growing a second portion of semiconductor material from and in contact with a top surface of the fin, said second portion of semiconductor material doped with a dopant of a second conductivity type; forming an insulated metal gate to straddle over said epitaxially grown second portion of semiconductor material on the fin; forming a source connection to the second portion of semiconductor material on one side of said insulated metal gate; and forming a drain connection to the second portion of semiconductor material on an opposite side of said insulated metal gate.

In an embodiment, a junctionless field effect transistor (FET) comprises: an insulating layer of a substrate; a fin on said insulating layer made of semiconductor material doped with a dopant of a first conductivity type; a channel made of an epitaxial semiconductor material region doped with a dopant of a second conductivity type and in contact with a top surface of the fin; an insulated metal gate straddling said channel; a source connection to the epitaxial semiconductor material region on one side of said insulated metal gate; and a drain connection to the epitaxial semiconductor material region on an opposite side of said insulated metal gate.

### BRIEF DESCRIPTION OF THE DRAWINGS

For a better understanding of the embodiments, reference will now be made by way of example only to the accompanying figures in which:

FIGS. 1-20C illustrate process steps in the formation of a junctionless FinFET device; and

FIGS. 21-32C illustrate process steps in the formation of a junctionless FinFET device.

### DETAILED DESCRIPTION OF THE DRAWINGS

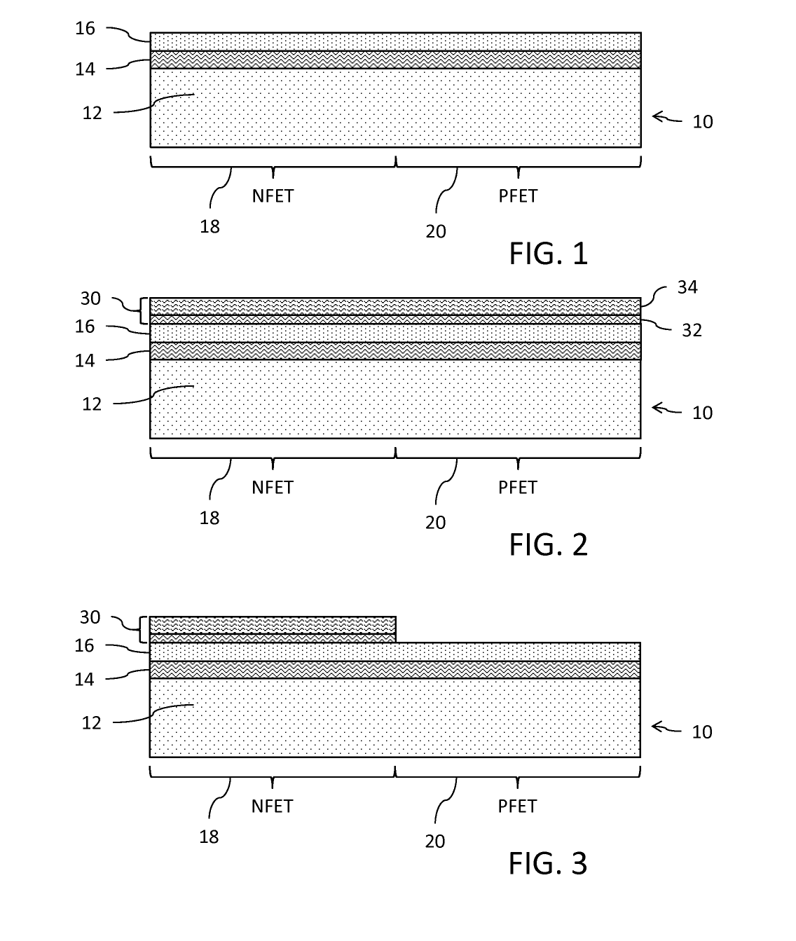

Reference is now made to FIGS. 1-20C which illustrate the process steps in the formation of a junctionless FinFET device. It will be understood that the drawings do not necessarily show features drawn to scale.

FIG. 1 shows a silicon on insulator (SOI) semiconductor substrate 10 comprising a semiconductor substrate 12, an insulating layer 14 and a semiconductor layer 16 in a stack. The semiconductor layer 16 may be doped in accordance with the application, or alternatively may be un-doped in which case the SOI substrate 10 is of the “fully-depleted” type. The semiconductor layer 16 may, for example, have a thickness of 5-10 nm. The insulating layer 14 is commonly referred to in the art as a buried oxide (BOX) layer. The substrate 10 includes an area 18 which is reserved for the formation of first polarity (n-channel) devices (NFET) and an area 20 which is reserved for the formation of second, opposite, polarity (p-channel) devices (PFET).

A hard mask 30 comprising a layer of silicon dioxide (SiO₂) 32 and a layer of silicon nitride (SiN) 34 is then deposited on the semiconductor layer 16. The silicon dioxide layer 32 may, for example, be deposited using a chemical vapor deposition (CVD) process with a thickness of, for example, approximately 3-5 nm. The silicon nitride layer 34 may, for example, be deposited using a chemical vapor deposition (CVD) process with a thickness of, for example, approximately 30-50 nm. The result is shown in FIG. 2.

Using lithographic techniques well known to those skilled in the art, a portion of the hard mask 30 is selectively removed from area 20 so as to expose a top surface of the semiconductor layer 16 in the area 20. The result is shown in FIG. 3.

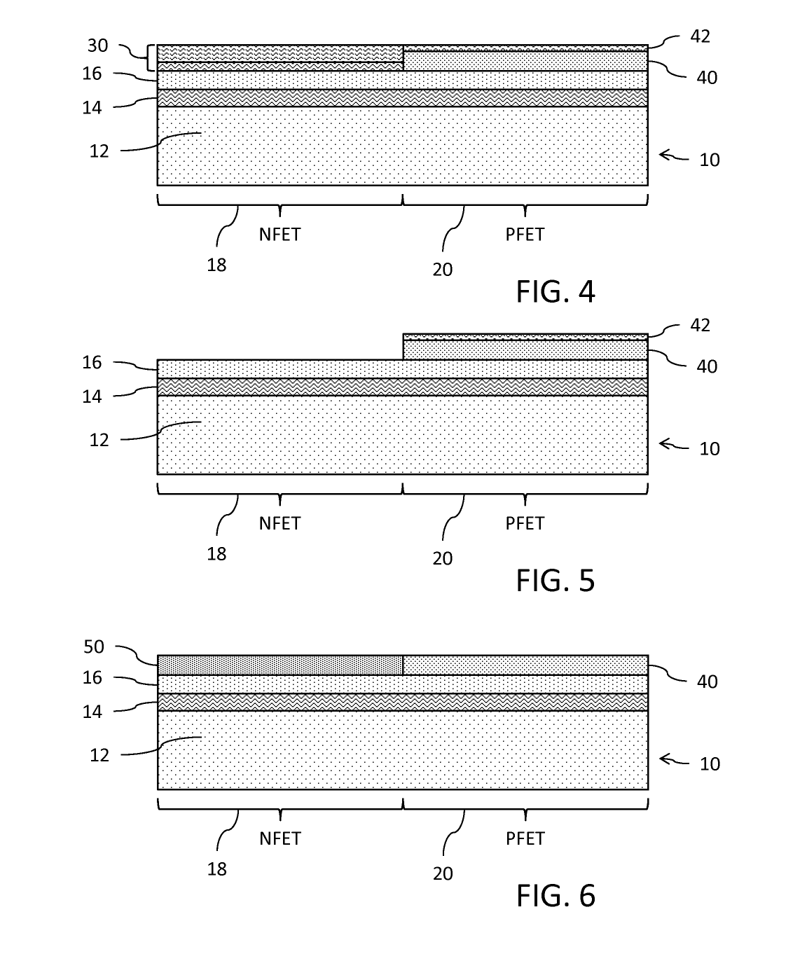

An epitaxial growth process as known in the art is performed to grow an epitaxial silicon region 40 from and in contact with the semiconductor layer 16 in the area 20. The epitaxial growth for silicon region 40 is preferably in situ doped with a suitable n-type dopant such as, for example, phosphorous. The silicon region 40 may, for example, have a dopant concentration of 1×10²⁰ at/cm³ and a thickness of 5-10 nm. A layer of silicon nitride (SiN) 42 is then deposited (for example, using atomic layer deposition to a thickness of 6-10 nm) to cover the epitaxial silicon region 40. The result of the epitaxial growth process to form epitaxial silicon region 40 (with protective layer 42) is shown in FIG. 4.

Using lithographic techniques well known to those skilled in the art, a portion of the hard mask 30 is selectively removed from area 18 so as to expose a top surface of the semiconductor layer 16 in the area 18. The result is shown in FIG. 5.

An epitaxial growth process as known in the art is performed to grow an epitaxial silicon-germanium (SiGe) region 50 from and in contact with the semiconductor layer 16 in the area 18. The epitaxial growth for silicon-germanium region 50 is preferably in situ doped with a suitable p-type dopant such as, for example, boron. A silicon-germanium material is preferably selected for the epitaxy here because it is easier to form in situ boron doped silicon-germanium than in situ boron doped silicon. The silicon-germanium region 50 may, for example, have a dopant concentration of 1×10²⁰ at/cm³ and a thickness of 5-10 nm. The previously deposited layer of silicon nitride 42 is then removed using a suitable etch (for example, a hot phosphoric acid etch). The result of the epitaxial growth process to form epitaxial silicon-germanium region 50 (with removal of protective layer 42) is shown in FIG. 6.

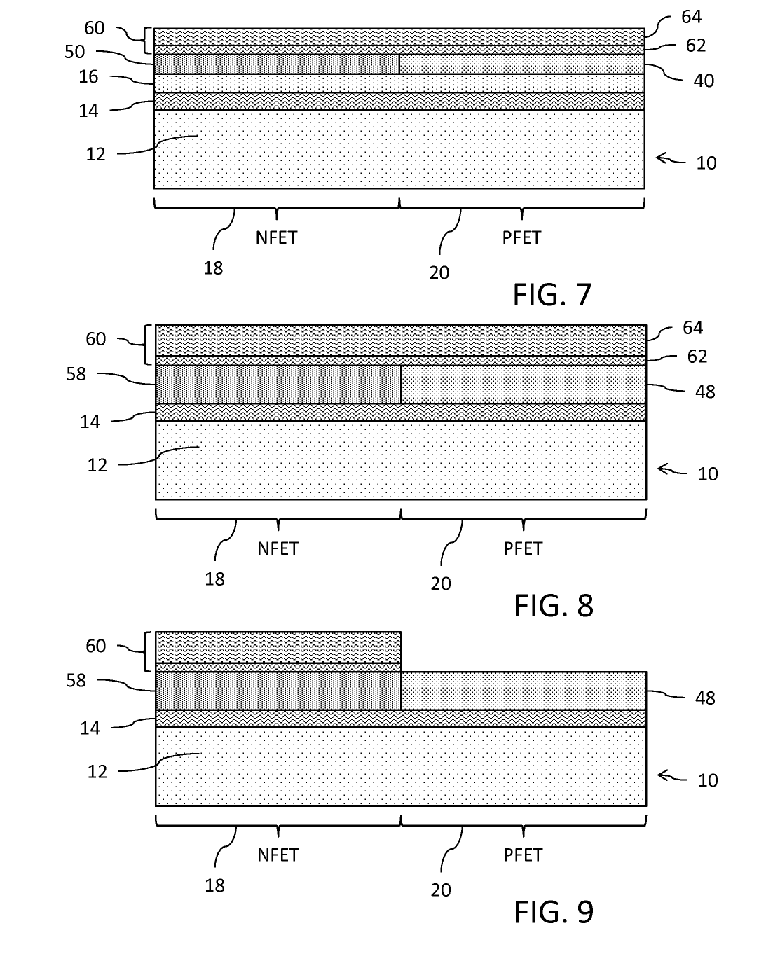

A hard mask 60 comprising a layer of silicon dioxide (SiO₂) 62 and a layer of silicon nitride (SiN) 64 is then deposited on the epitaxial regions 40 and 50. The silicon dioxide layer 62 may, for example, be deposited using a chemical vapor deposition (CVD) process with a thickness of, for example, approximately 3-5 nm. The silicon nitride layer 64 may, for example, be deposited using a chemical vapor deposition (CVD) process with a thickness of, for example, approximately 20-40 nm. The result is shown in FIG. 7.

A high temperature anneal is then performed to drive the n-type and p-type dopants from the epitaxial regions 40 and 50, respectively, into the semiconductor layer 16 so as to form an n-type doped silicon region 48 and a p-type doped silicon-germanium region 58 above the buried oxide layer 14. It will be noted that this anneal further converts the silicon material of layer 16 in region 18 to silicon-germanium. The result is shown in FIG. 8.

Using lithographic techniques well known to those skilled in the art, a portion of the hard mask 60 is selectively removed from area 20 so as to expose a top surface of the n-type doped silicon region 48 in the area 20. The result is shown in FIG. 9.

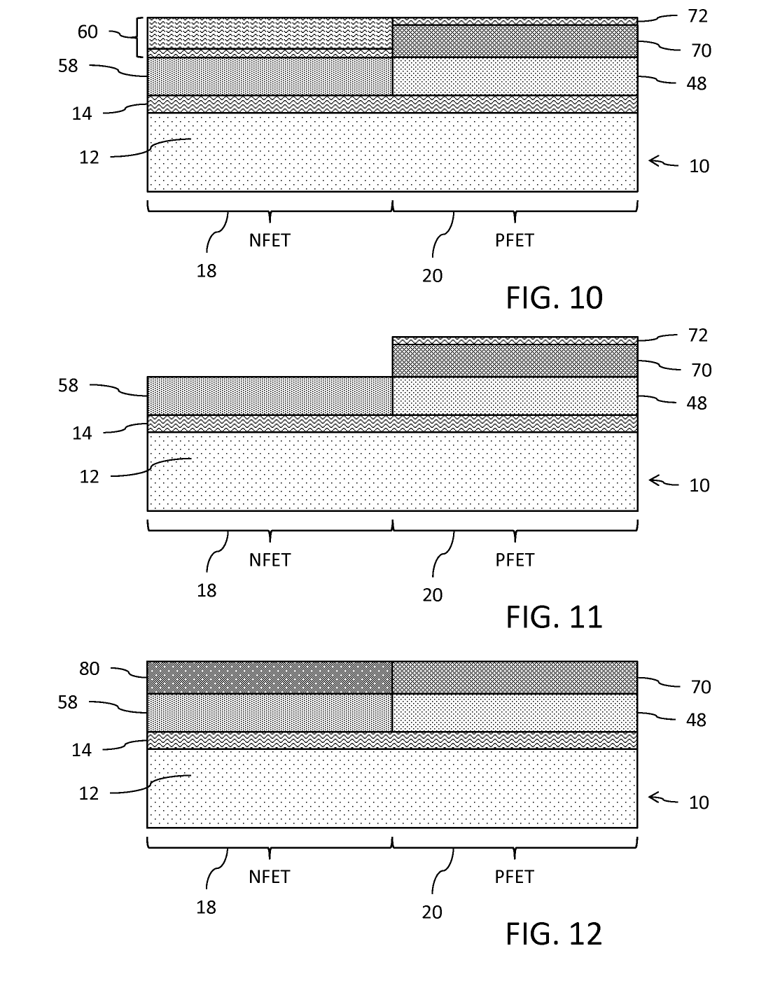

An epitaxial growth process as known in the art is performed to grow an epitaxial silicon-germanium (SiGe) region 70 from and in contact with a top surface of the n-type doped silicon region 48 in the area 20. As the area 20 is associated with the formation of p-type polarity devices, in particular junctionless p-type FET devices as will be shown, the epitaxial growth for silicon-germanium region 70 is preferably in situ doped with a suitable p-type dopant such as, for example, boron. A silicon-germanium material is preferred here because it provides a higher hole mobility than silicon for use in the junctionless device channel. The silicon-germanium region 70 may, for example, have a dopant concentration of 5×10¹⁹ to 1×10²⁰ at/cm³ and a thickness of 25-45 nm. A layer of silicon nitride (SiN) 72 is then deposited (for example, using atomic layer deposition to a thickness of 6-10 nm) to cover the epitaxial silicon-germanium region 70. The result of the epitaxial growth process to form epitaxial silicon-germanium region 70 (with protective layer 72) is shown in FIG. 10.

Using lithographic techniques well known to those skilled in the art, a portion of the hard mask 60 is selectively removed from area 18 so as to expose a top surface of the p-type doped silicon-germanium region 58 in the area 18. The result is shown in FIG. 11.

An epitaxial growth process as known in the art is performed to grow an epitaxial silicon region 80 from and in contact with a top surface of the p-type doped silicon-germanium region 58 in the area 18. As the area 18 is associated with the formation of n-type polarity devices, in particular junctionless n-type FET devices as will be shown, the epitaxial growth for silicon region 80 is preferably in situ doped with a suitable n-type dopant such as, for example, phosphorous. The silicon region 80 may, for example, have a dopant concentration of 5×10¹⁹ to 1×10²⁰ at/cm³ and a thickness of 25-45 nm. The previously deposited layer of silicon nitride 72 is then removed using a suitable etch (for example, a hot phosphoric acid etch). The result of the epitaxial growth process to form epitaxial silicon region 80 (with removal of protective layer 72) is shown in FIG. 12. Although silicon material is preferred for this epitaxy due to the n-type channel for the junctionless device, it will be understood that region 80 may instead comprise silicon-germanium.

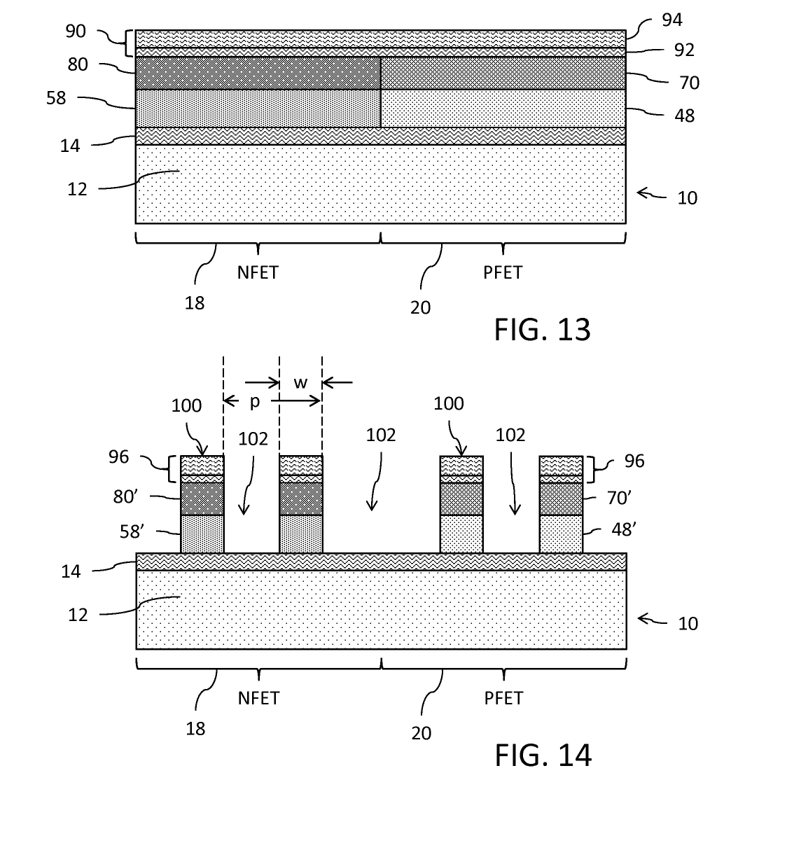

A hard mask 90 comprising a layer of silicon dioxide (SiO₂) 92 and a layer of silicon nitride (SiN) 94 is then deposited on the epitaxial regions 70 and 80. The silicon dioxide layer 92 may, for example, be deposited using a chemical vapor deposition (CVD) process with a thickness of, for example, approximately 3-5 nm. The silicon nitride layer 94 may, for example, be deposited using a chemical vapor deposition (CVD) process with a thickness of, for example, approximately 20-40 nm. The result is shown in FIG. 13.

A lithographic process as known in the art is then used to define a plurality of fins 100 from the doped material of the regions 48, 58, 70 and 80. The hard mask 90 is patterned to leave mask material 96 at the desired locations of the fins 100. An etching operation is then performed through the mask to open apertures 102 on each side of each fin 100. In a preferred embodiment, the etch which defines the fins 100 extends to a depth which reaches the insulating layer 14. In each of the areas 18 and 20, the fins 40 may have a width (w) of 6-15 nm and a pitch (p) of 20-50 nm. The result of the etching process is shown in FIG. 14 with each fin 100 in area 20 comprising a portion 80′ of region 80 in contact with a top surface of a portion 58′ of region 58, and each fin 100 in area 18 comprising a portion 70′ of region 70 in contact with a top surface of a portion 48′ of region 48.

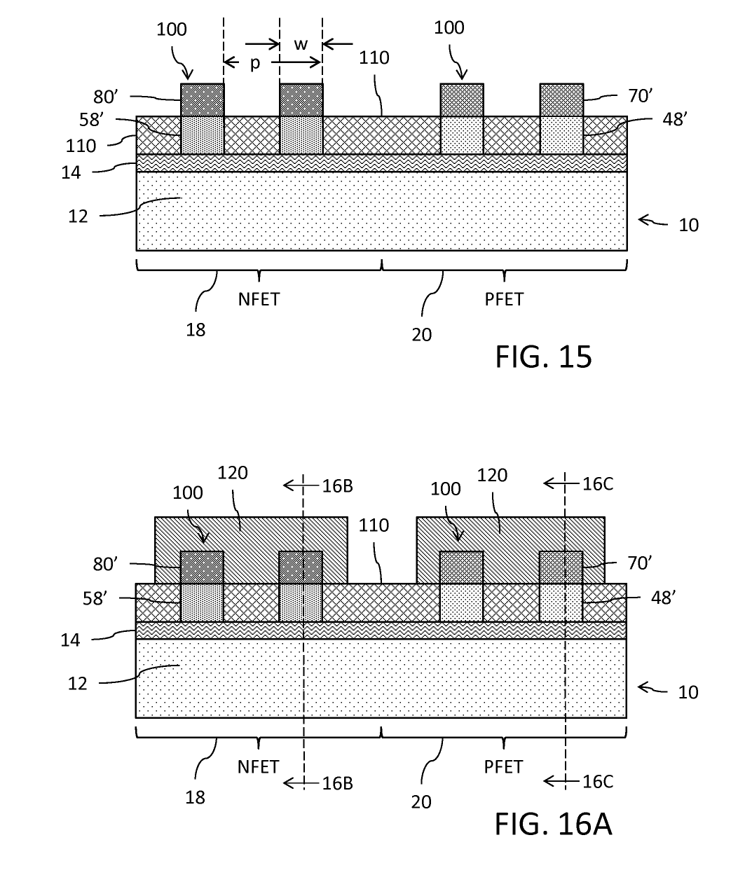

An insulating material such as a flowable silicon oxide is then deposited. This deposition covers the fins 100. A planarization followed by a dry etch (COR or SiCoNi) is then performed to recess the silicon oxide deposit to form an insulation layer 110 to locally insulate bottom portions of the fins 100 from each other. The insulation layer 110 preferably has a thickness of 10-20 nm so as to equal or exceed the thickness of the portions 48′ and 58′ of each fin 100. This leaves approximately 30-40 nm of each fin 100 exposed (corresponding generally to the thickness of the portions 70′ and 80′). The mask material 96 is also removed. The result is shown in FIG. 15.

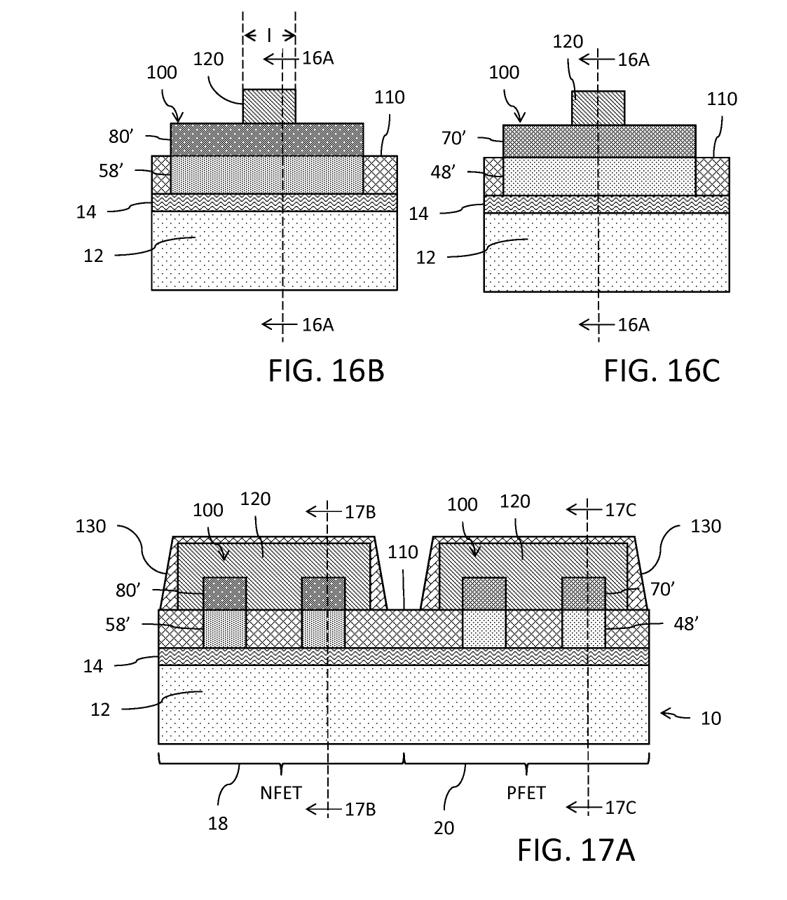

A polysilicon material deposition is then performed to cover the fins 100. After a planarization, standard lithographic techniques are then used to pattern the polysilicon material deposit to define a dummy gate structure 120 in each area 18 and 20 that straddles the fins 100 with a bridge portion of the dummy gate structure positioned above the fin 100 and leg portions of the dummy gate structure (extending from the bridge portion) positioned on opposite sides of the fin 100. The gate structures 120 may, for example, have a gate length (I) of 15-30 nm. The result is shown in FIGS. 16A, 16B and 16C.

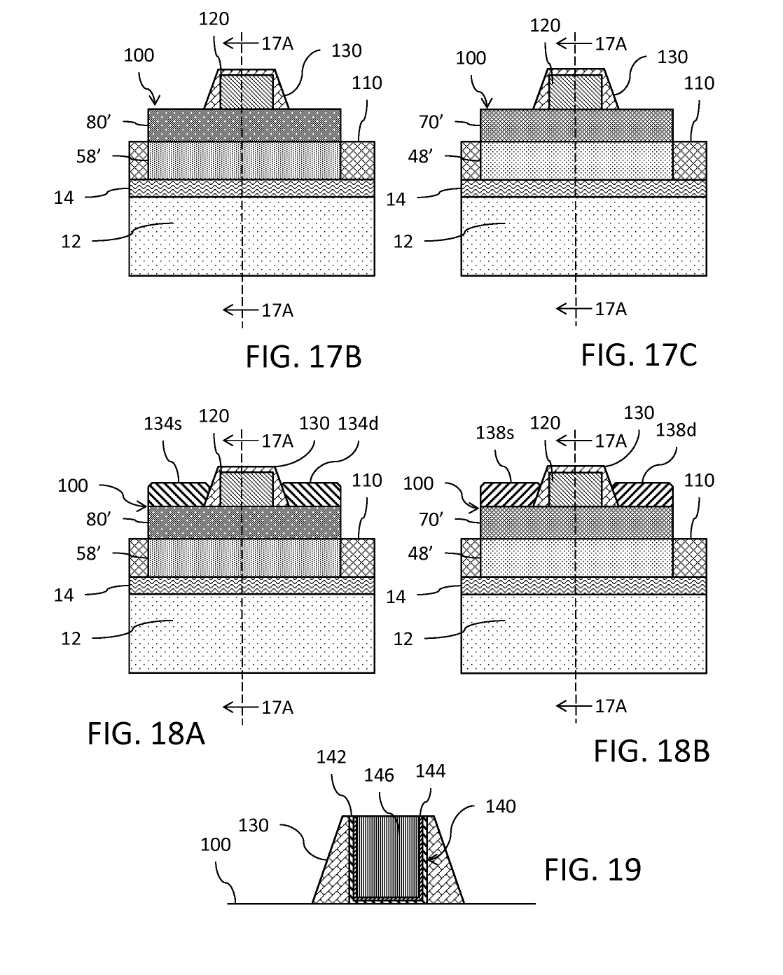

A conformal insulating material deposit is then made with a subsequent directional etch performed to define sidewall spacers 130 on the side surfaces of the dummy gate structures 120. The result is shown in FIGS. 17A, 17B and 17C.

Source-drain connections then need to be made to the portion 80′ of fin 100 on each side of the gate. After blocking off the area 20, an epitaxial growth process as known in the art is performed to grow silicon or silicon-carbide (SiC) raised source-drain regions 134s and 134d from and in contact with the upper surface of the fins 100 in area 18. The raised source-drain regions 134s and 134d are preferably in situ doped with a suitable n-type dopant such as, for example, phosphorous to match the dopant type used for portion 80′ of fin 100. The raised source-drain regions 134s and 134d may, for example, have a dopant concentration of 1×10²⁰ to 5×10²⁰ at/cm³ and a thickness of 10-40 nm. The result is shown in FIG. 18A.

Source-drain connections then need to be made to the portion 70′ of fin 100 on each side of the gate. After blocking off the area 18, an epitaxial growth process as known in the art is performed to grow silicon or silicon-germanium (SiGe) raised source-drain regions 138s and 138d from and in contact with the upper surface of the fins 100 in area 20. The raised source-drain regions 138s and 138d are preferably in situ doped with a suitable p-type dopant such as, for example, boron to match the dopant type used for portion 70′ of fin 100. The raised source-drain regions 138s and 138d may, for example, have a dopant concentration of 1×10²⁰ to 5×10²⁰ at/cm³ and a thickness of 10-40 nm. The result is shown in FIG. 18B.

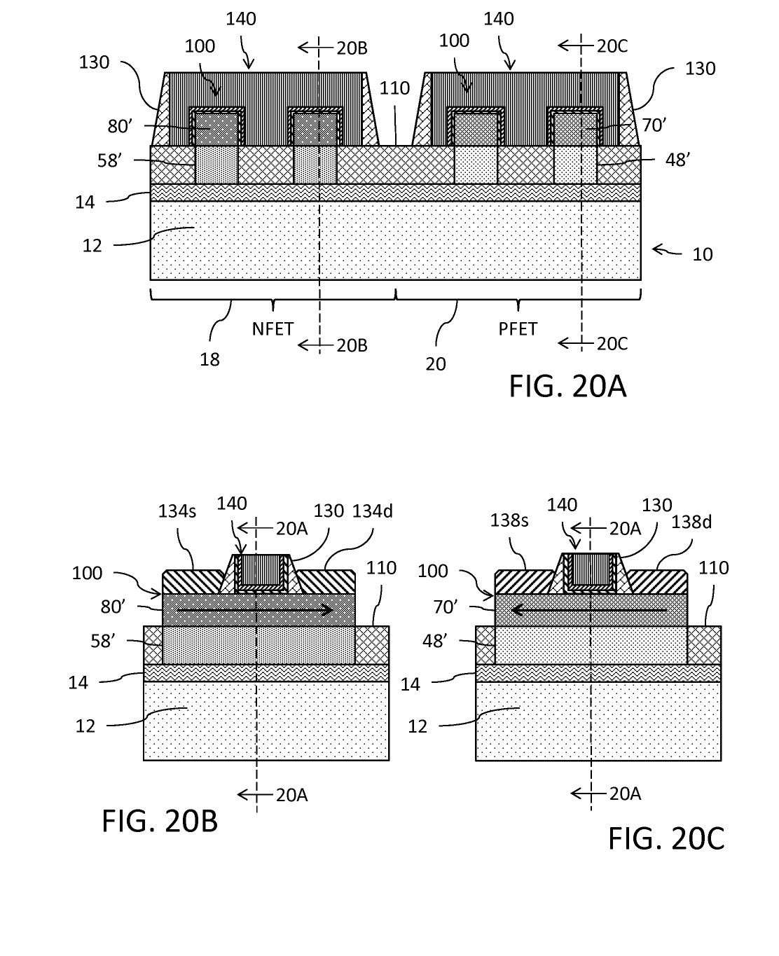

The replacement metal gate process, as known in the art, is then performed to access and remove the dummy gate structure 120 in each area 18 and 20. After the dummy gate structures 120 are removed, the resulting opening between the sidewall spacers 130 is filled with a replacement metal gate 140 which, like the dummy gate structure it is replacing, straddles the fins 100 with a bridge portion of the replacement gate structure positioned above each fin 100 and leg portions of the replacement dummy gate structure (extending from the bridge portion) positioned on opposite sides of each fin 100. The replacement metal gate 140 comprises a high-k dielectric gate insulating layer 142 (for example, made of hafnium-oxide) with a thickness of, for example, 1-3 nm, a metal gate liner 144 (for example, made of titanium nitride or titanium carbide) with a thickness of 3-5 nm, and a metal fill 146 (for example, made of tungsten). See, FIGS. 19 and 20A-20C.

Conventional back end of line (BEOL) processes are then performed to deposit and planarize the premetallization dielectric (PMD) layer and form metal contacts to the source, drain and gate regions of the junctionless FET device. The raised source-drain regions support the formation of silicide regions to improve contact resistance. Current flow in the devices when turned on is illustrated by the arrows in FIGS. 20B and 20C.

A junctionless transistor is accordingly formed with the portions 70′ and 80′ of the fins 100 forming channel structures for the current carrying channel of the transistor device and the replacement metal gate 140 forming the insulated control gate for the transistor device. Thus, for each of the junctionless NFET and PFET devices, the channels are formed of monocrystalline epitaxial semiconductor material which exhibits reduced defects and better resistivity than the amorphous semiconductor material typically used in prior art devices. The channels are supported by the portions 48′ and 58′ of the fins 100 which are made of semiconductor material of opposite conductivity type. These portions 48′ and 58′ do not function in the current carrying operation of the NFET and PFET junctionless devices, but their presence contributes to improving device performance in terms of a noted decrease in swing and increase in current as compared to prior art devices.

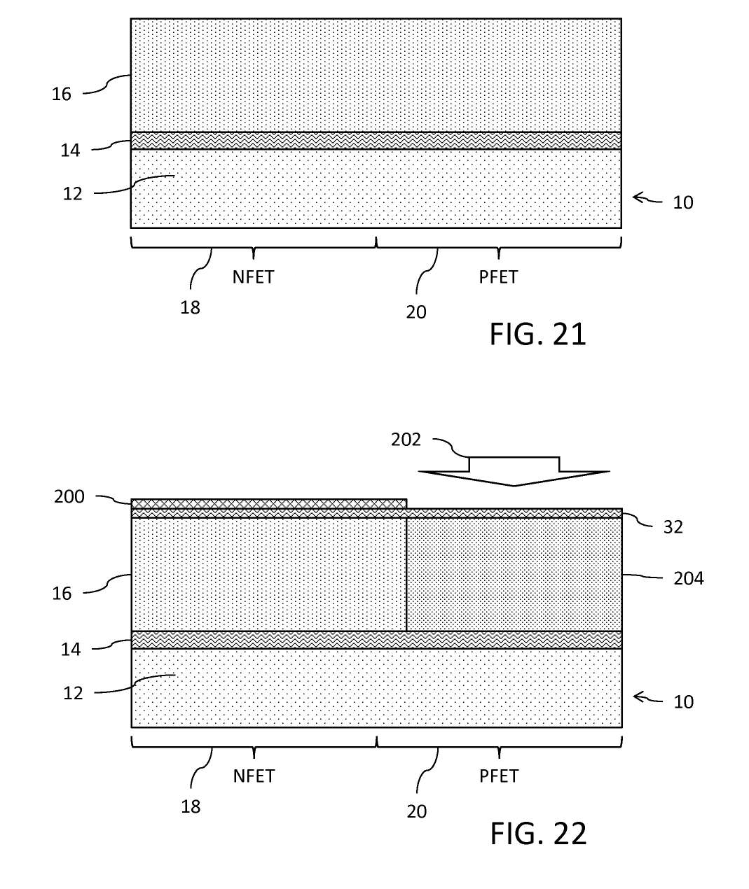

Reference is now made to FIGS. 21-32C which illustrate the process steps in the formation of a junctionless FinFET device. It will be understood that the drawings do not necessarily show features drawn to scale.

FIG. 21 shows a silicon on insulator (SOI) semiconductor substrate 10 comprising a semiconductor substrate 12, an insulating layer 14 and a semiconductor layer 16 in a stack. The semiconductor layer 16 may be doped in accordance with the application, or alternatively may be un-doped in which case the SOI substrate 10 is of the “fully-depleted” type. The semiconductor layer 16 may, for example, have a thickness of 30-50 nm. The insulating layer 14 is commonly referred to in the art as a buried oxide (BOX) layer. The substrate 10 includes an area 18 which is reserved for the formation of first polarity (n-channel) devices (NFET) and an area 20 which is reserved for the formation of second, opposite, polarity (p-channel) devices (PFET).

A layer of silicon dioxide (SiO₂) 32 is then deposited on the semiconductor layer 16. The silicon dioxide layer 32 may, for example, be deposited using a chemical vapor deposition (CVD) process with a thickness of, for example, approximately 3-5 nm.

Next, the area 18 is blocked off (reference 200) and an implant 202 of n-type dopants (such as, for example, arsenic or phosphorous) is made in semiconductor layer 16 of the substrate 10 to define an n-type semiconductor region 204. The result is shown in FIG. 22.

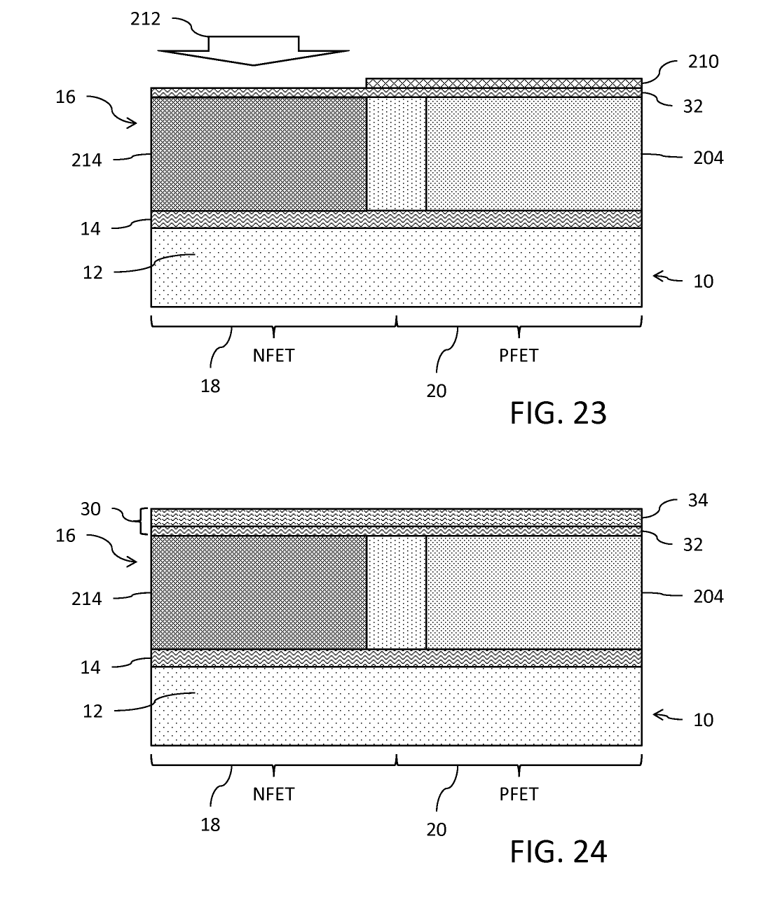

Next, the area 20 is blocked off (reference 210) and an implant 212 of p-type dopants (such as, for example, boron) is made in semiconductor layer 16 of the substrate 10 to define a p-type semiconductor region 214. The result is shown in FIG. 23.

A layer of silicon nitride (SiN) 34 is then deposited on the silicon dioxide layer 32 to form a hard mask 30. The silicon nitride layer 34 may, for example, be deposited using a chemical vapor deposition (CVD) process with a thickness of, for example, approximately 30-50 nm. The result is shown in FIG. 24.

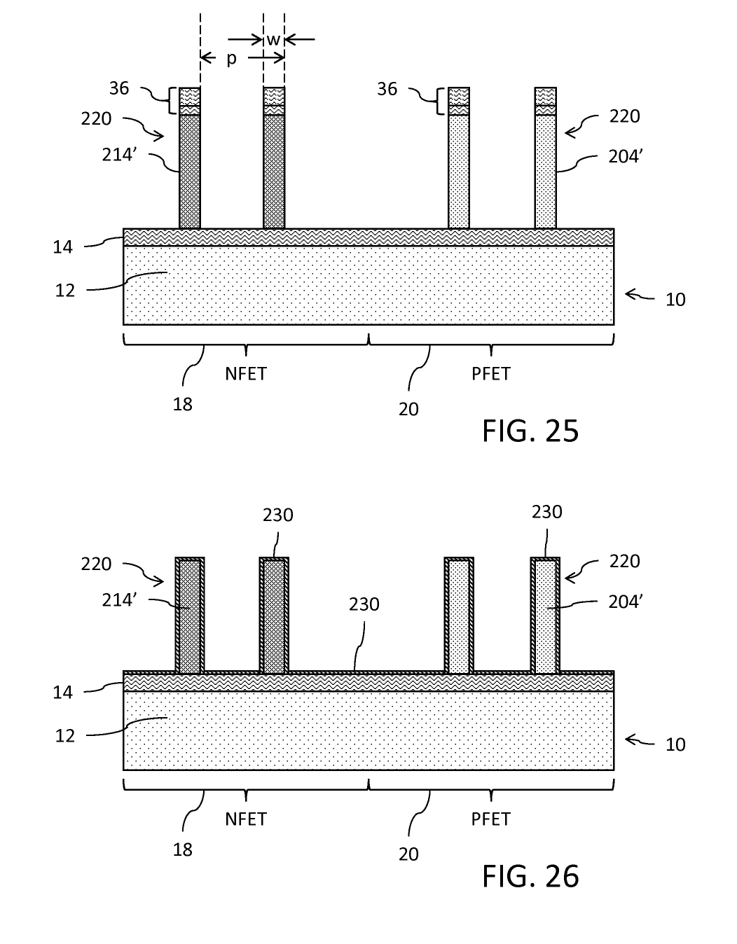

A lithographic process as known in the art is then used to define a plurality of fins 220 from the doped material of the regions 204 and 214. The hard mask 30 is patterned to leave mask material 36 at the desired locations of the fins 220. An etching operation is then performed through the mask to open apertures 222 on each side of each fin 220. In a preferred embodiment, the etch which defines the fins 220 extends to a depth which reaches the insulating layer 14. In each of the areas 18 and 20, the fins 220 may have a width (w) of 4-8 nm and a pitch (p) of 20-50 nm. The result of the etching process is shown in FIG. 25 with each fin 220 formed by a corresponding portion 204′ and 214′ of the regions 204 and 214.

A silicon nitride liner 230 is then deposited to cover the fins 220. The deposition may, for example, be made using an atomic layer deposition (ALD) process. The liner 230 may, for example, have a thickness of 2-6 nm. The result is shown in FIG. 26.

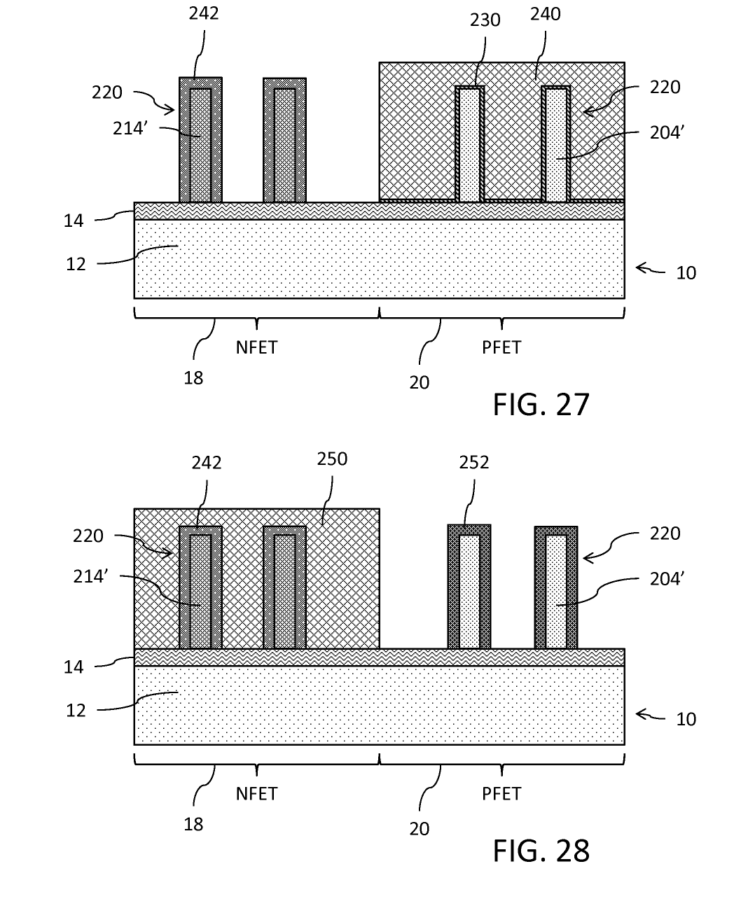

Next, the area 20 is blocked off (reference 240), the liner 230 is removed from the fins 220 in the area 18 (using any suitable wet or dry etch technique) to expose the top and opposed side surfaces of the fins 220, and an epitaxial growth process as known in the art is performed to grow a silicon or silicon-carbide (SiC) channel structure 242 from and in contact with the exposed top and opposed side surfaces of each fin 220. As the portions 214′ of fins 220 in area 18 are of p-type, and the area 18 is associated with the formation of junctionless transistors of the n-type polarity, the epitaxially grown channel structures 242 are also of n-type. Preferably, the epitaxial growth is in situ doped with a suitable n-type dopant such as, for example, arsenic. The channel structures 242 may, for example, have a thickness of 5-10 nm and a dopant concentration of 5×10¹⁹ to 1×10²⁰ at/cm³. The result of the epitaxial growth process is shown in FIG. 27. The blocking mask (reference 240) is then removed.

Next, the area 18 is blocked off (reference 250 including a new silicon nitride liner (not explicitly shown) on the channel structures 242), the liner 230 is removed from the fins 220 in the area 20 (using any suitable wet or dry etch technique) to expose the top and opposed side surfaces of the fins 220, and an epitaxial growth process as known in the art is performed to grow a silicon or silicon-germanium (SiGe) channel structure 252 from and in contact with the exposed top and opposed side surfaces of each fin 220. As the portions 204′ of fins 220 in area 20 are of n-type, and the area 20 is associated with the formation of junctionless transistors of the p-type polarity, the epitaxially grown channel structures 252 are also of p-type. Preferably, the epitaxial growth is in situ doped with a suitable p-type dopant such as, for example, boron. The channel structures 252 may, for example, have a thickness of 5-10 nm and a dopant concentration of 5×10¹⁹ to 1×10²⁰ at/cm³. The result of the epitaxial growth process is shown in FIG. 28. The blocking mask (reference 250, with the included silicon nitride liner) is then removed.

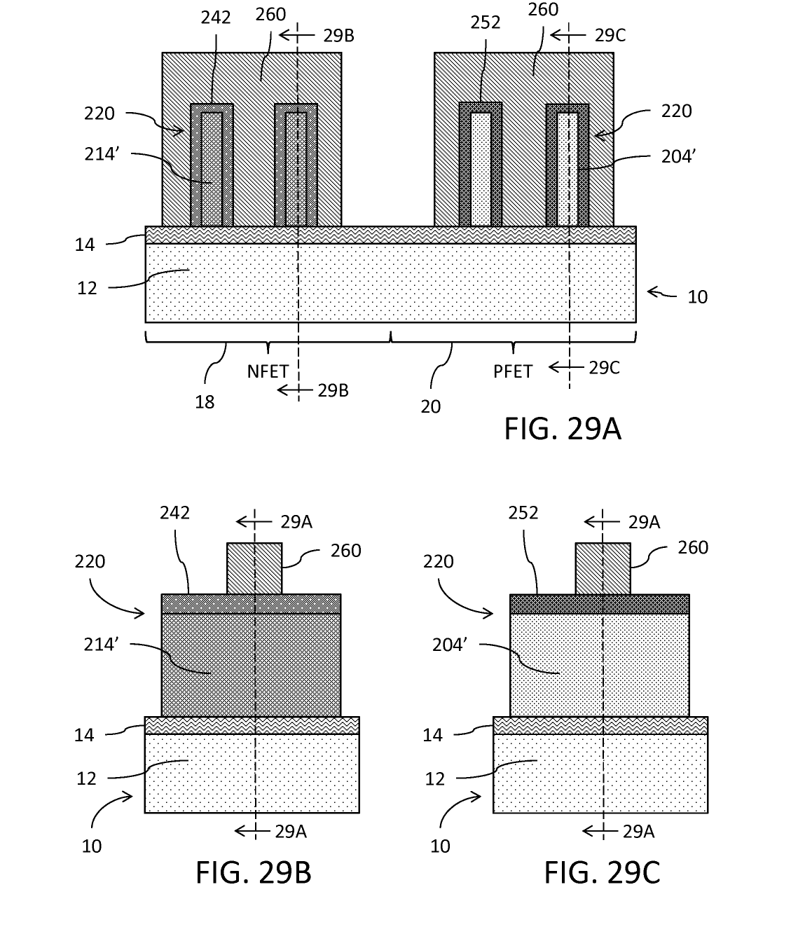

A polysilicon material deposition is then performed to cover the fins 220. After a planarization, standard lithographic techniques are then used to pattern the polysilicon material deposit to define a dummy gate structure 260 in each area 18 and 20 that straddles the fins 220 covered by the channel structures 242 and 252, with a bridge portion of the dummy gate structure positioned above each fin 220 and leg portions of the dummy gate structure (extending from the bridge portion) positioned on opposite sides of each fin 220. The gate structures 260 may, for example, have a gate length (I) of 15-30 nm. The result is shown in FIGS. 29A, 29B and 29C.

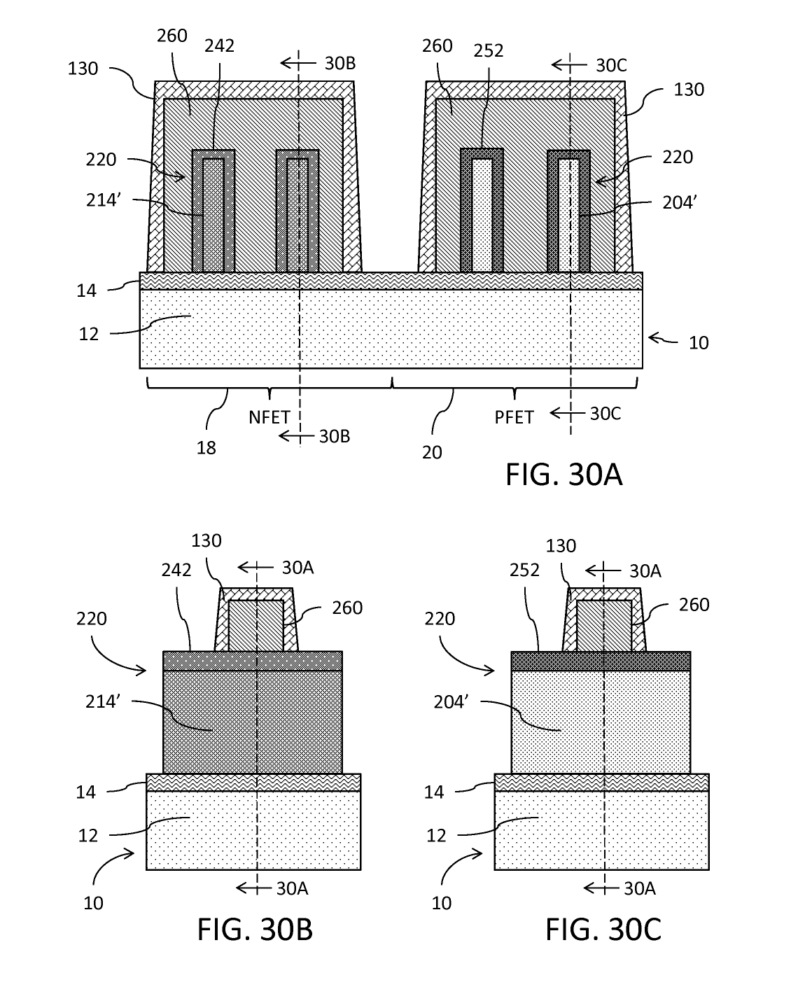

A conformal insulating material deposit is then made with a subsequent directional etch performed to define sidewall spacers 130 on the side surfaces of the dummy gate structures 260. The result is shown in FIGS. 30A, 30B and 30C.

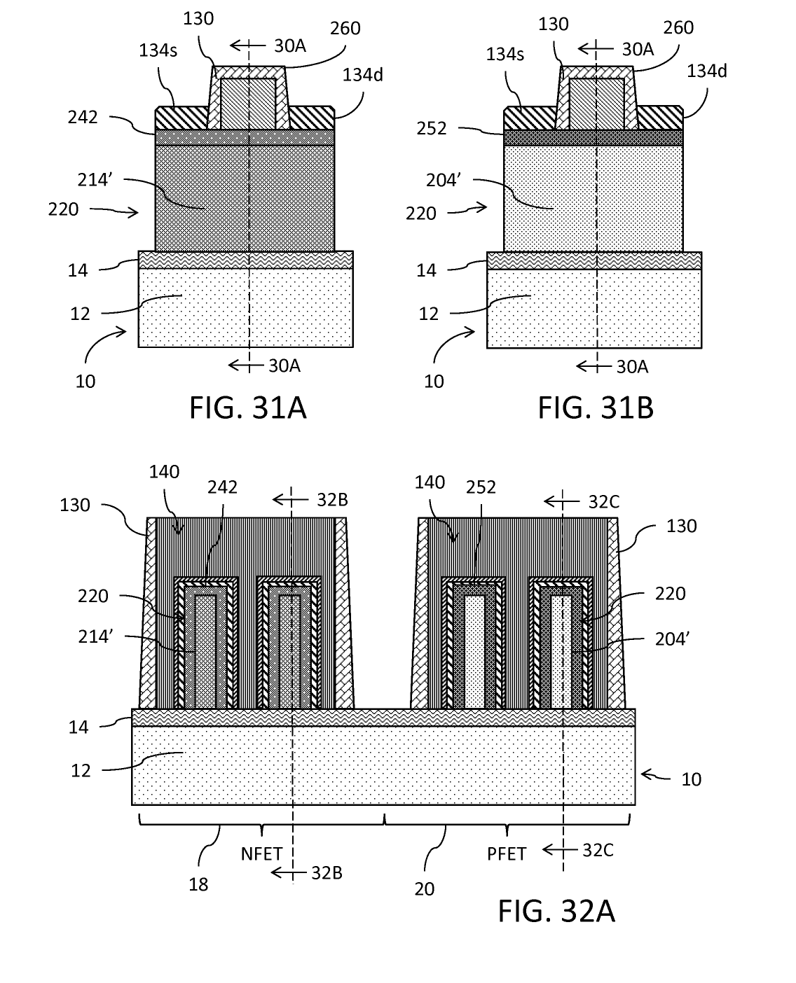

Source-drain connections then need to be made to the channel structure 242 of fin 220 on each side of the gate. After blocking off the area 20, an epitaxial growth process as known in the art is performed to grow silicon or silicon-carbide (SiC) raised source-drain regions 134s and 134d from and in contact with the upper surface of the channel structure 242 on the fins 220 in area 18. The raised source-drain regions 134s and 134d are preferably in situ doped with a suitable n-type dopant such as, for example, phosphorous to match the dopant type used for channel structure 242. The raised source-drain regions 134s and 134d may, for example, have a dopant concentration of 1×10²⁰ to 5×10²⁰ at/cm³ and a thickness of 10-40 nm. The result is shown in FIG. 31A.

Source-drain connections then need to be made to the channel structure 252 of fin 220 on each side of the gate. After blocking off the area 18, an epitaxial growth process as known in the art is performed to grow silicon or silicon-germanium (SiGe) raised source-drain regions 138s and 138d from and in contact with the upper surface of the channel structure 252 on the fins 220 in area 20. The raised source-drain regions 138s and 138d are preferably in situ doped with a suitable p-type dopant such as, for example, boron to match the dopant type used for channel structure 252. The raised source-drain regions 138s and 138d may, for example, have a dopant concentration of 1×10²⁰ to 5×10²⁰ at/cm³ and a thickness of 10-40 nm. The result is shown in FIG. 31B.

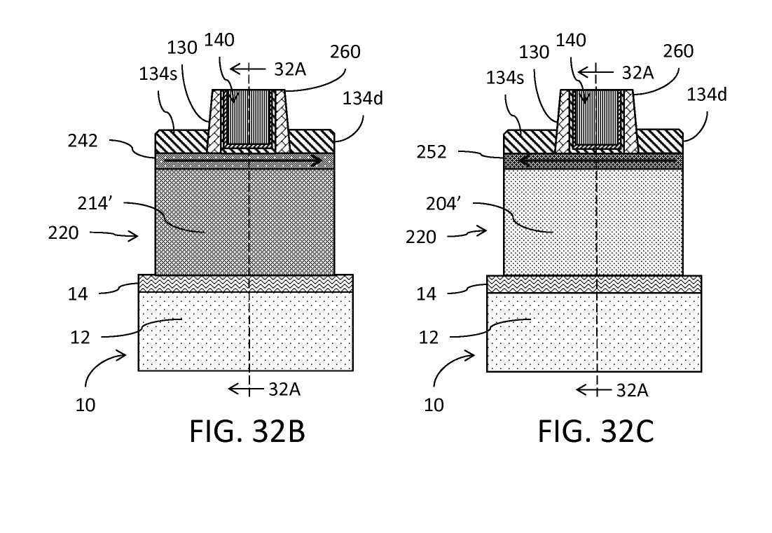

The replacement metal gate process, as known in the art, is then performed to access and remove the dummy gate structure 260 in each area 18 and 20. After the dummy gate structures 260 are removed, the resulting opening between the sidewall spacers 130 is filled with a replacement metal gate 140 which, like the dummy gate structure it is replacing, straddles the fins 220 with a bridge portion of the replacement gate structure positioned above each fin 100 and leg portions of the replacement gate structure (extending from the bridge portion) positioned on opposite sides of each fin 100. The replacement metal gate 140 comprises a high-k dielectric gate insulating layer 142 (for example, made of hafnium-oxide) with a thickness of, for example, 1-3 nm, a metal gate liner 144 (for example, made of titanium nitride or titanium carbide) with a thickness of 3-5 nm, and a metal fill 146 (for example, made of tungsten). See, FIGS. 19 and 32A-32C.

Conventional back end of line (BEOL) processes are then performed to deposit and planarize the premetallization dielectric (PMD) layer and form metal contacts to the source, drain and gate regions. The raised source-drain regions support the formation of silicide regions to improve contact resistance. Current flow in the devices when turned on is illustrated by the arrows in FIGS. 32B and 32C.

A junctionless transistor is accordingly formed with the channel structures 242 and 252 of the fins 220 forming the current carrying channel of the transistor device and the replacement metal gate 140 forming the insulated control gate for the transistor device. Thus, for each of the junctionless NFET and PFET devices, the channels are formed of monocrystalline epitaxial semiconductor material which exhibits reduced defects and better resistivity than the amorphous semiconductor material typically used in prior art devices. The channels surround the portions 204′ and 214′ of semiconductor material of the fins 220 of opposite conductivity type. These fins 220 do not function in the current carrying operation of the NFET and PFET junctionless devices, but their presence contributes to improving device performance in terms of a noted decrease in swing and increase in current as compared to prior art devices.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. An integrated circuit transistor device, comprising:
an insulating layer of a substrate;
a fin on said insulating layer, said fin comprising:
a first portion of semiconductor material doped with a dopant of a first conductivity type; and
a second portion of semiconductor material doped with a dopant of a second conductivity type, said second portion comprising epitaxial material grown from and in contact with a top surface of the first portion of semiconductor material;
an insulated metal gate straddling said fin;
a source connection to the second portion of semiconductor material on one side of said insulated metal gate; and
a drain connection to the second portion of semiconductor material on an opposite side of said insulated metal gate.

2. The integrated circuit transistor device of claim 1, wherein said substrate is of a silicon on insulator (SOI) type.

3. The integrated circuit transistor device of claim 2, said SOI type substrate having a semiconductor layer, and wherein said first portion of semiconductor material is formed from said semiconductor layer.

4. The integrated circuit transistor device of claim 1, wherein said first portion of semiconductor material further includes opposed side surfaces, and wherein said material of the second portion of semiconductor material is grown from and in contact with the opposed side surfaces of the first portion of semiconductor material.

5. The integrated circuit transistor device of claim 1, wherein the integrated circuit transistor device is a junctionless field effect transistor (FET), and wherein said second portion of semiconductor material forms a channel structure of the junctionless FET.

6. The integrated circuit transistor device of claim 5, wherein the junctionless FET is a p-type polarity device.

7. The integrated circuit transistor device of claim 5, wherein the junctionless FET is an n-type polarity device.

8. The integrated circuit transistor device of claim 1:
wherein the source connection comprises an epitaxial raised source region grown from and in contact with a top surface of the second portion of semiconductor material on said one side of said insulated metal gate; and
wherein the drain connection comprises an epitaxial raised drain region grown from and in contact with a top surface of the second portion of semiconductor material on said opposite side of said insulated metal gate.

9. A method, comprising:
patterning semiconductor material doped with a dopant of a first conductivity type to form a fin on an insulating layer of a substrate;
epitaxially growing a second portion of semiconductor material from and in contact with a top surface of the fin, said second portion of semiconductor material doped with a dopant of a second conductivity type;
forming an insulated metal gate to straddle over said epitaxially grown second portion of semiconductor material on the fin;
forming a source connection to the second portion of semiconductor material on one side of said insulated metal gate; and
forming a drain connection to the second portion of semiconductor material on an opposite side of said insulated metal gate.

10. The method of claim 9, wherein said substrate is of a silicon on insulator (SOI) type.

11. The method of claim 10, said SOI type substrate having a semiconductor layer, and further comprising, before said step of patterning, doping said semiconductor layer with said dopant of the first conductivity type to form a first conductivity type region, and wherein said step of patterning comprises etching the first conductivity type region to form said fin.

12. The method of claim 10, said SOI type substrate having a semiconductor layer, and further comprising, before said step of patterning:
epitaxially growing an epitaxial region of semiconductor material on said semiconductor layer and doped with said dopant of the first conductivity type; and
annealing to drive first conductivity type dopant from said epitaxial region into said semiconductor layer; and
wherein said step of patterning comprises etching the epitaxial region to form said fin.

13. The method of claim 9, wherein said fin further includes opposed side surfaces, and wherein said step of epitaxially growing comprises epitaxially growing said material of the second portion of semiconductor material from and in contact with the opposed side surfaces of the fin.

14. The method of claim 9, wherein said epitaxially grown second portion of semiconductor material on the fin forms a channel structure of a junctionless field effect transistor (FET).

15. The method of claim 14, wherein the junctionless FET is a p-type polarity device.

16. The method of claim 14, wherein the junctionless FET is an n-type polarity device.

17. The method of claim 9:
wherein the step of forming the source connection comprises epitaxially growing a raised source region from and in contact with a top surface of the second portion of semiconductor material on said one side of said insulated metal gate; and
wherein the step of forming the drain connection comprises epitaxially growing a raised drain region from and in contact with a top surface of the second portion of semiconductor material on said opposite side of said insulated metal gate.

18. An integrated circuit, comprising:
an insulating layer of a substrate;
a first junctionless field effect transistor (FET) of a first polarity type, comprising:
a first fin on said insulating layer made of semiconductor material doped with a dopant of a first conductivity type;
a first channel made of a first epitaxial semiconductor material region doped with a dopant of a second conductivity type and in contact with a top surface of the first fin;
a first insulated metal gate straddling said first channel;
a first source connection to the first epitaxial semiconductor material region on one side of said first insulated metal gate; and
a first drain connection to the first epitaxial semiconductor material region on an opposite side of said first insulated metal gate.

19. The integrated circuit of claim 18, wherein said first fin includes opposed side surfaces, and wherein said first epitaxial semiconductor material region is in contact with the opposed side surfaces of the first fin.

20. The integrated circuit of claim 18:
wherein the first source connection comprises an epitaxial raised source region grown from and in contact with a top surface of the first channel on said one side of said insulated metal gate; and
wherein the first drain connection comprises an epitaxial raised drain region grown from and in contact with a top surface of the second channel on said opposite side of said insulated metal gate.

21. The integrated circuit of claim 18, further comprising a second junctionless FET of a second, opposite, polarity type, comprising:
a second fin on said insulating layer made of semiconductor material doped with the dopant of the second conductivity type;
a second channel made of a second epitaxial semiconductor material region doped with the dopant of the first conductivity type and in contact with a top surface of the second fin;
a second insulated metal gate straddling said second channel;
a second source connection to the second epitaxial semiconductor material region on one side of said second insulated metal gate; and
a second drain connection to the second epitaxial semiconductor material region on an opposite side of said second insulated metal gate.

22. The integrated circuit of claim 21, wherein the first junctionless FET is a p-type polarity device and the second junctionless FET is an n-type polarity device.
